(19) United States
(12) Patent Application Publication
(10) Pub. No.: US 2023/0061128 A1
(43) Pub. Date: Mar. 2, 2023

(54) MEMORY DEVICE AND METHOD OF FABRICATING THE SAME

(71) Applicant: MACRONIX International Co., Ltd., Hsinchu (TW)

(72) Inventor: Chin-Cheng Yang, Kaohsiung City (TW)

(73) Assignee: MACRONIX International Co., Ltd., Hsinchu (TW)

(21) Appl. No.: 17/464,479

(22) Filed: Sep. 1, 2021

(51) Int. Cl. H01L 23/60; H01L 23/535; H01L 27/11556; H01L 27/11582; H01L 21/768

(52) U.S. Cl. CPC H01L 23/60; H01L 23/535; H01L 27/11556; H01L 27/11582; H01L 21/76805; H01L 21/76895

(57) ABSTRACT

A memory device includes a substrate, a metal interconnect structure, a first stack structure, a second stack structure, a first conductive pillar, and a first contact. The metal interconnect structure is located on the substrate. The first stack structure is located on the metal interconnect structure and includes first conductive layers and first insulating layer that alternate with each other, and an insulating structure embedded in the first conductive layers and the first insulating layers. The second stack structure is located on the first stack structure and includes second insulating layers and middle layers that alternate with each other. The first conductive pillar is embedded in the insulating structure to be electrically connected to the metal interconnect structure. The first contact passes through the second insulating layers and the middle layers of the second stack structure to be electrically connected to the first conductive pillar.

### BACKGROUND

### Technical Field

The embodiment of the disclosure relates to a semiconductor device and a method of fabricating the same, and particularly, to a memory device and a method of fabricating the same.

### Description of Related Art

Since a non-volatile memory device (e.g., a flash memory) has the advantage that stored data does not disappear at power-off, it becomes a widely used memory device for a personal computer or other electronics equipment.

Currently, the flash memory array commonly used in the industry includes a NOR flash memory and a NAND flash memory. Since the NAND flash memory has a structure in which memory cells are connected together in series, degree of integration and area utilization thereof are better than those of the NOR flash memory. Thus, the NAND flash memory has been widely used in a variety of electronic products. Besides, to further enhance the degree of integration of the memory device, a three-dimensional NAND flash memory is developed. However, there are still some challenges associated with the three-dimensional NAND flash memory. For example, due to a difference in the depths of contacts in different regions, the process window may be too small.

### SUMMARY

The embodiments of the disclosure provide a memory device that can reduce the difference in the depths of contacts in different regions to increase the process window.

An embodiment of the disclosure provides a memory device including a substrate, a metal interconnect structure, a first stack structure, a second stack structure, a first conductive pillar, and a first contact. The metal interconnect structure is located on the substrate. The first stack structure is located on the metal interconnect structure and includes a plurality of first conductive layers and a plurality of first insulating layers that alternate with each other, and an insulating structure embedded in the first conductive layers and the first insulating layers. The second stack structure is located on the first stack structure and includes a plurality of second insulating layers and a plurality of middle layers that alternate with each other. The first conductive pillar is embedded in the insulating structure to be electrically connected to the metal interconnect structure. The first contact passes through the second insulating layers and the middle layers of the second stack structure to be electrically connected to the first conductive pillar.

An embodiment of the disclosure provides a method of fabricating a memory device, including the following steps. A metal interconnect structure is formed on a substrate. A first stack structure is formed on the metal interconnect structure, and the first stack structure includes a plurality of first conductive layers and a plurality of first insulating layers that alternate with each other. An insulating structure is formed in the first stack structure. A first conductive pillar is formed in the insulating structure. A second stack structure is formed on the first stack structure, the insulating structure, and the first conductive pillar, and the second stack structure includes a plurality of second insulating layers and a plurality of middle layers that alternate with each other. A first contact is formed to pass through the second insulating layers and the middle layers of the second stack structure to be electrically connected to the first conductive pillar.

Based on the above, in the embodiments of the disclosure, since the through array contact is formed in multiple stages, it is possible to reduce the etching loading effect, reduce the difference in the depths of contact openings in different regions, and increase the process window.

### BRIEF DESCRIPTION OF THE DRAWINGS

FIG. 1A to FIG. 1M are schematic cross-sectional views showing a method of fabricating a three-dimensional memory device according to an embodiment of the disclosure.

FIG. 2, FIG. 3A, FIG. 3B, FIG. 4A, FIG. 4B, FIG. 5A, and FIG. 5B are schematic cross-sectional views showing three-dimensional memory devices according to multiple embodiments of the disclosure.

### DESCRIPTION OF THE EMBODIMENTS

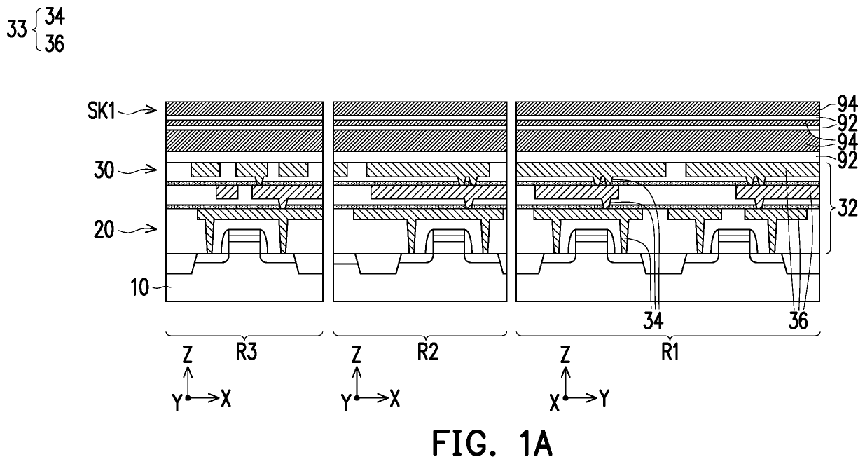

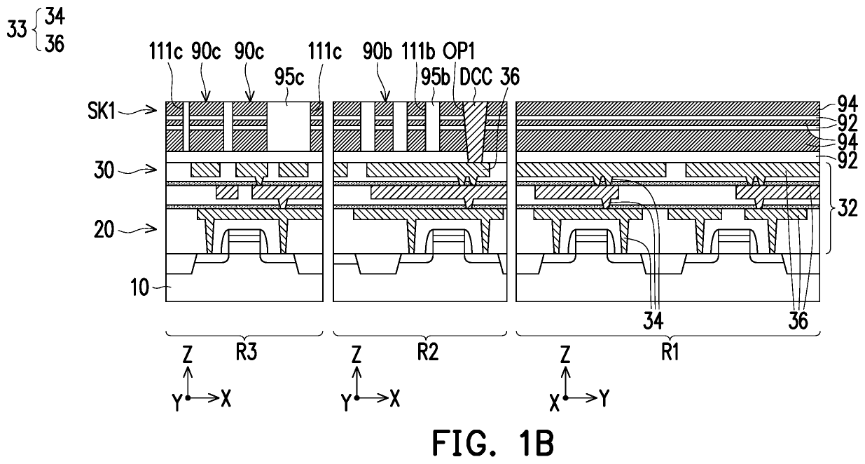

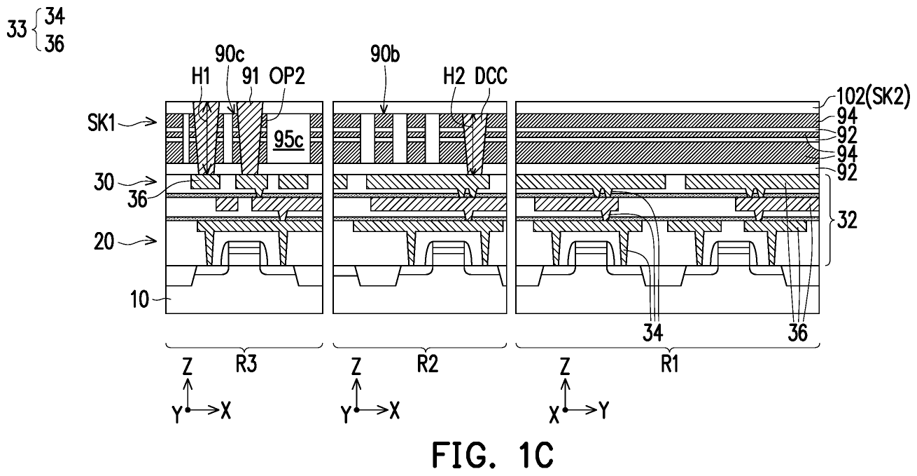

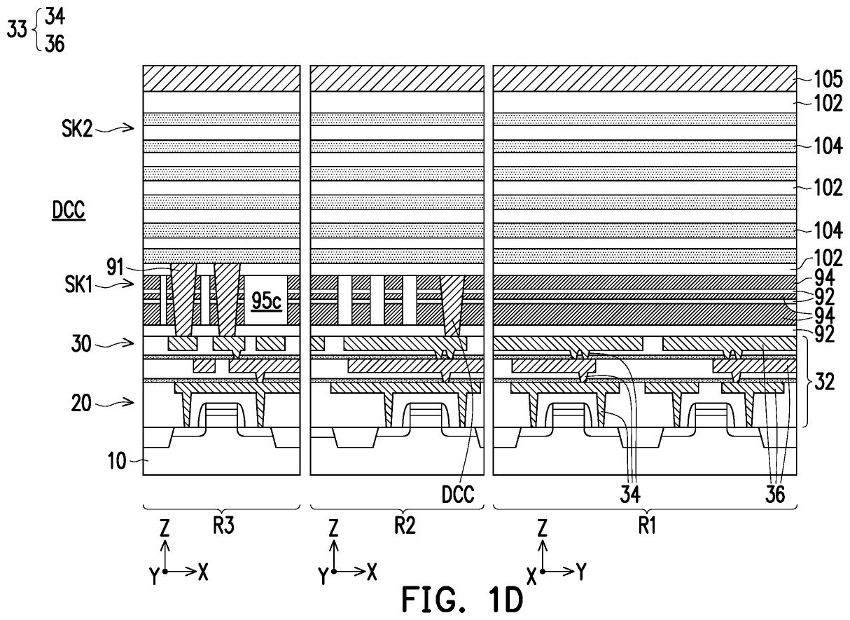

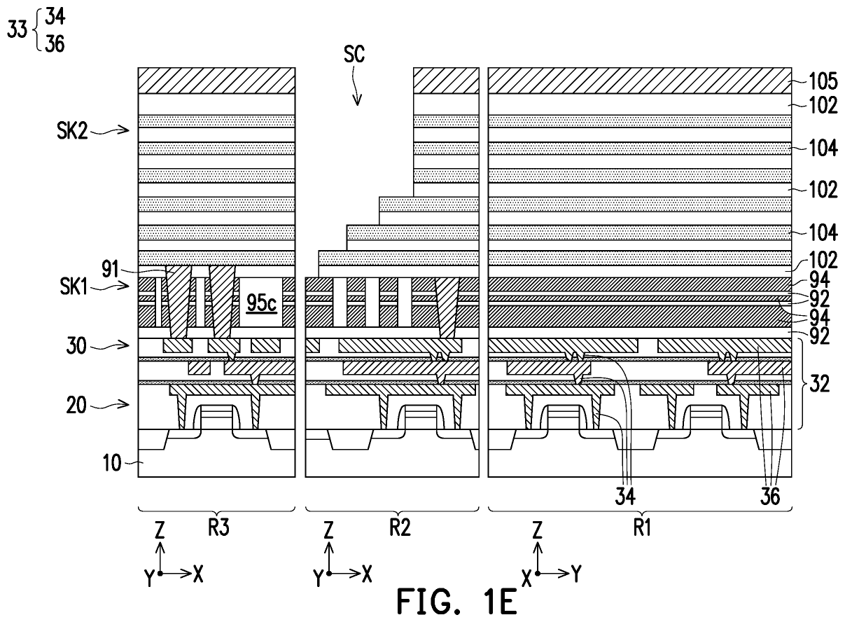

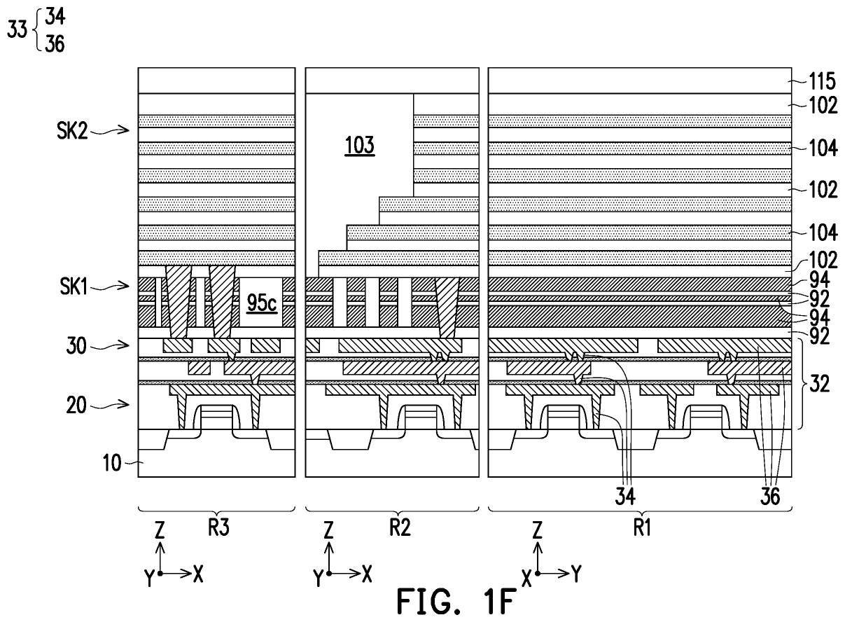

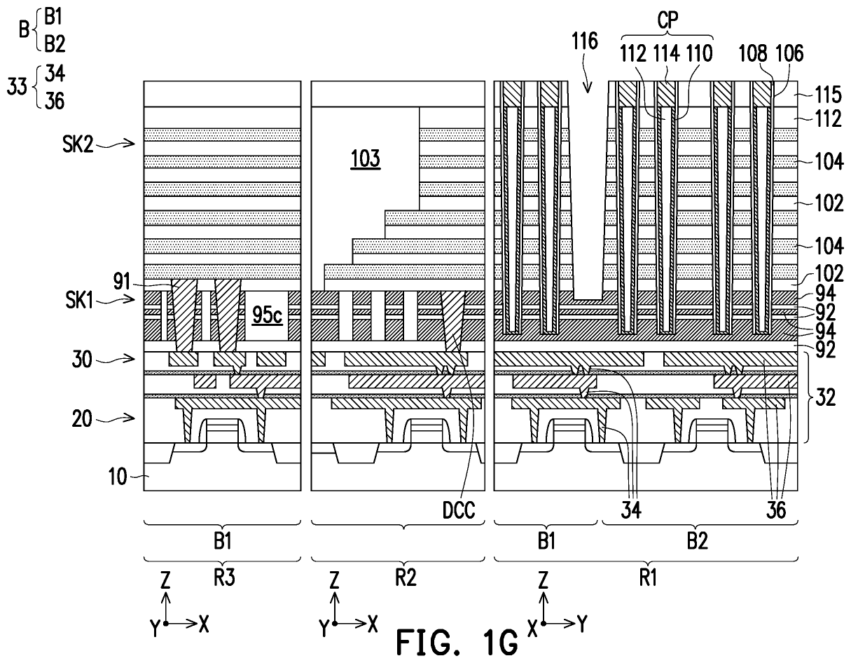

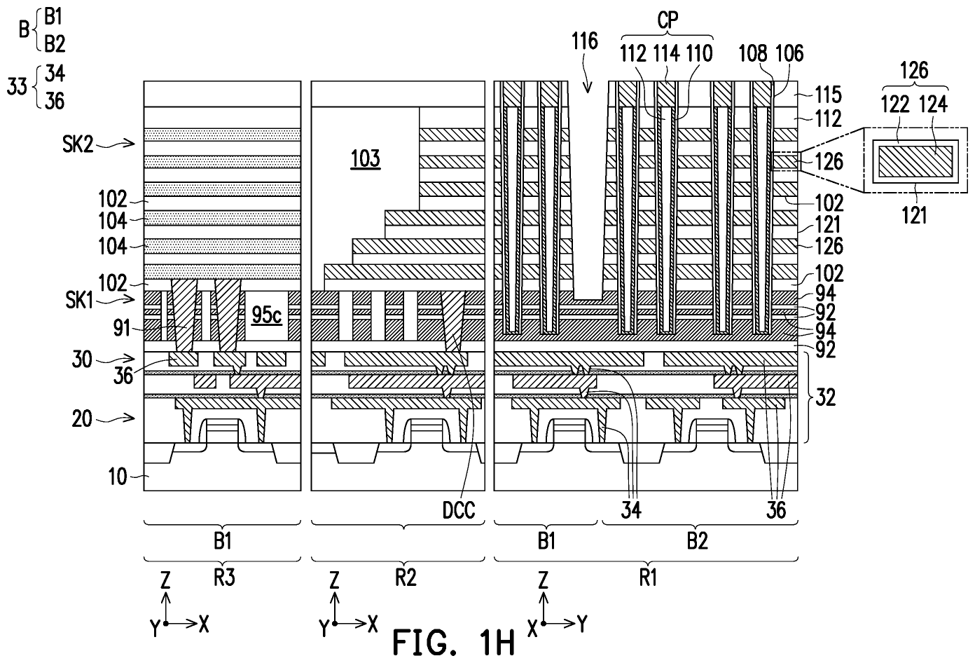

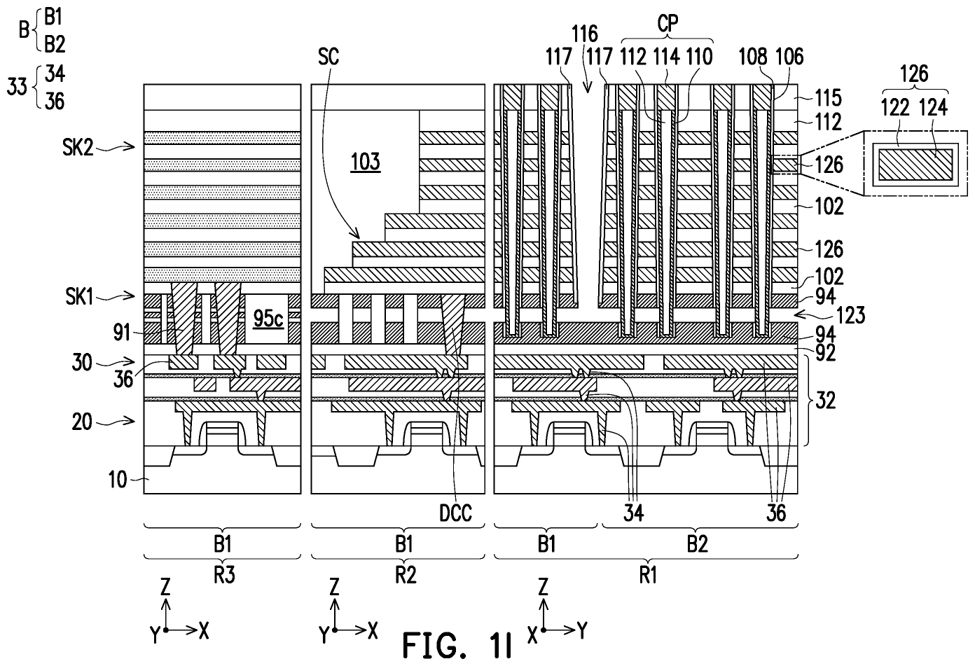

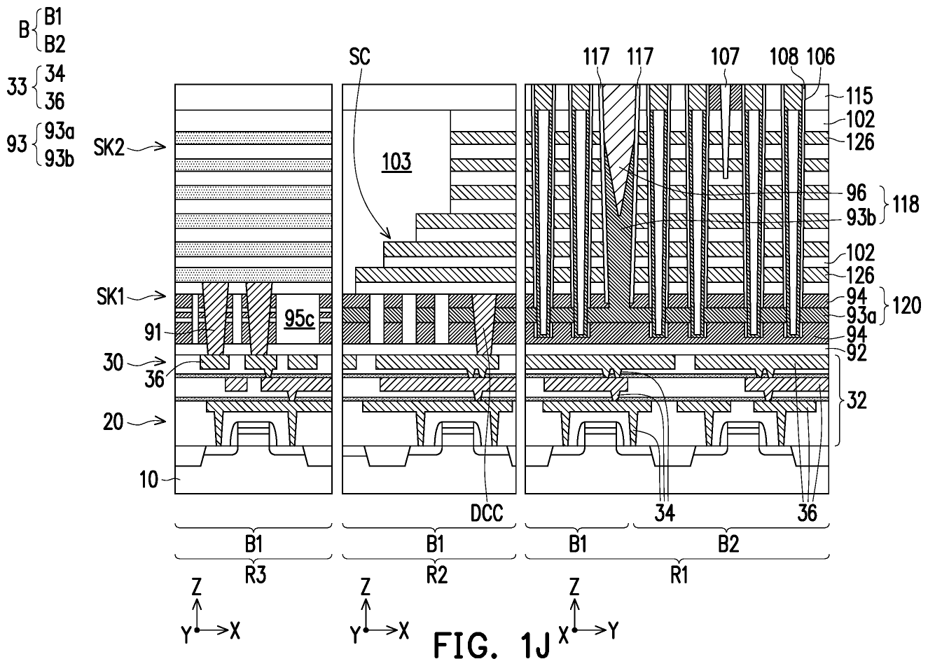

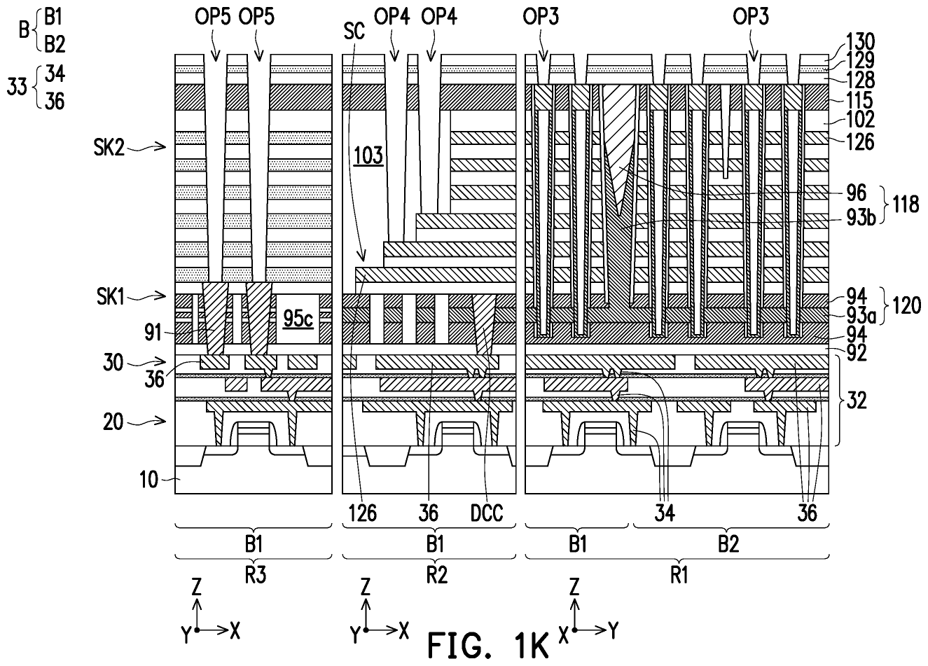

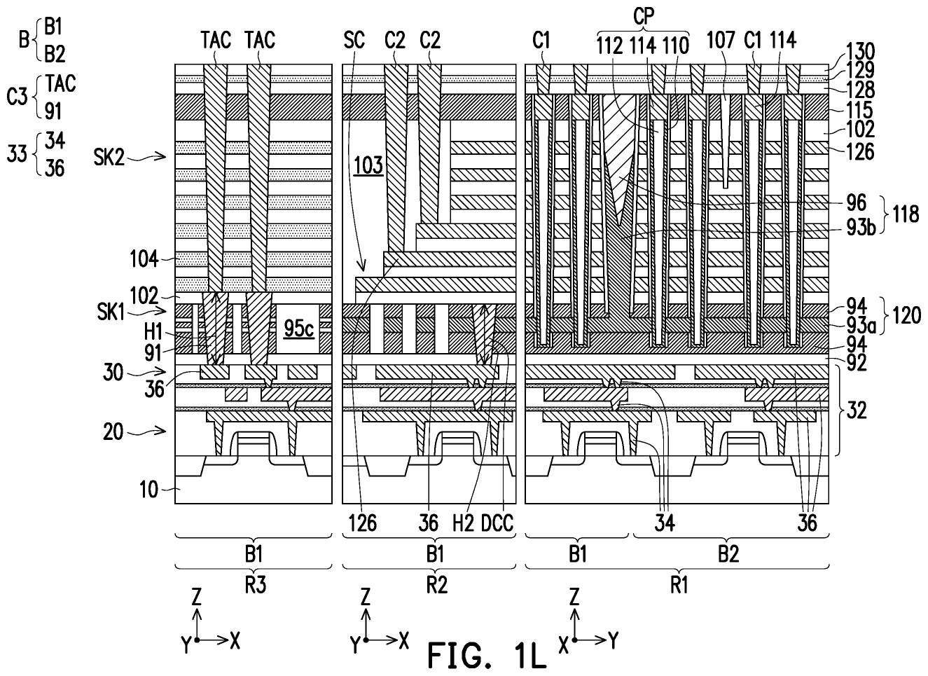

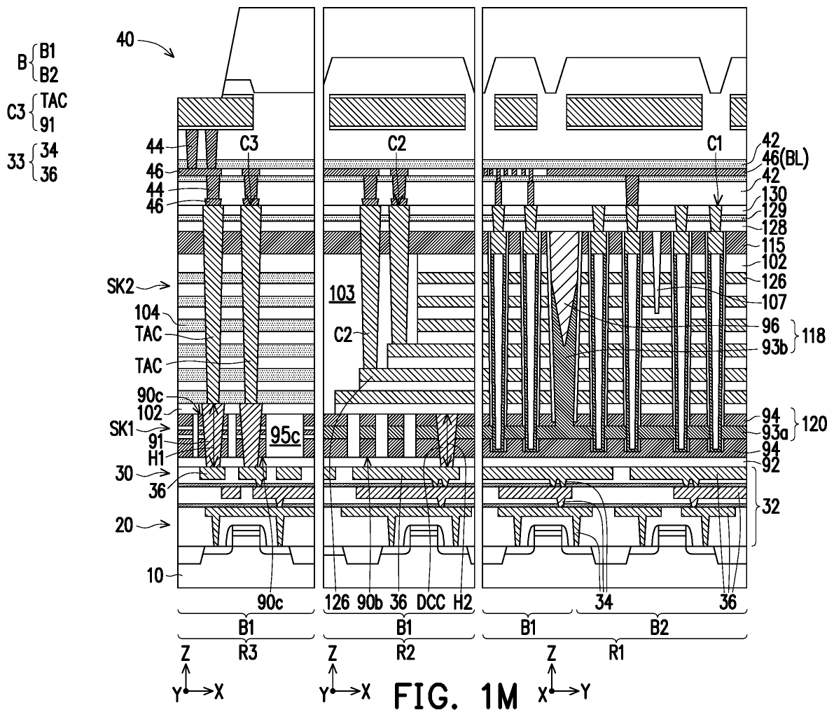

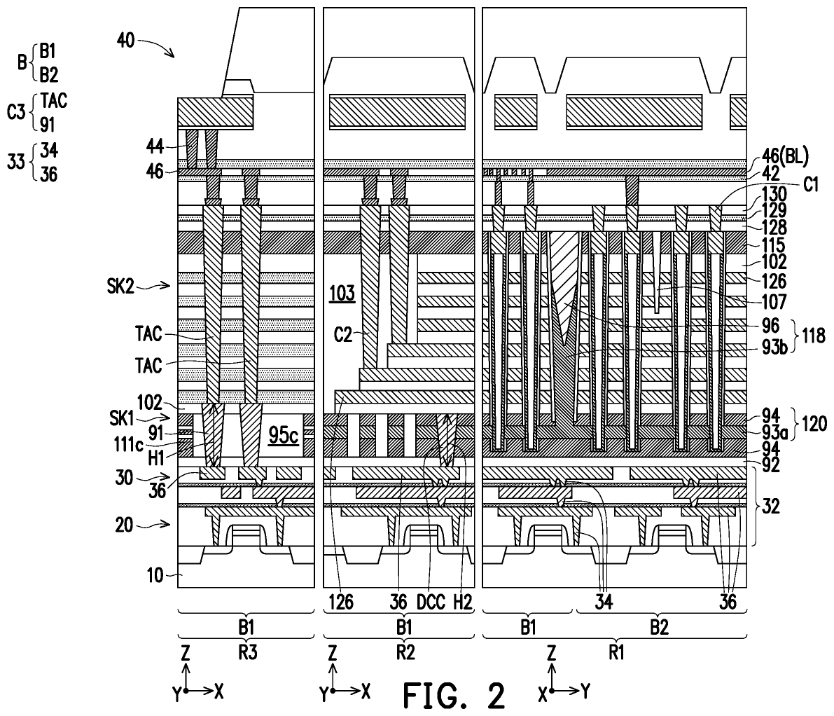

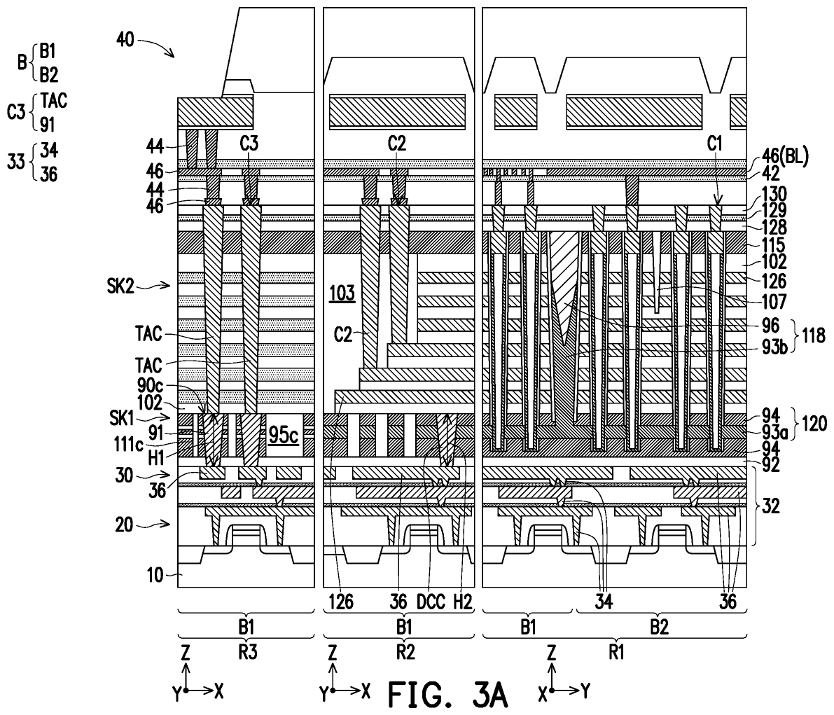

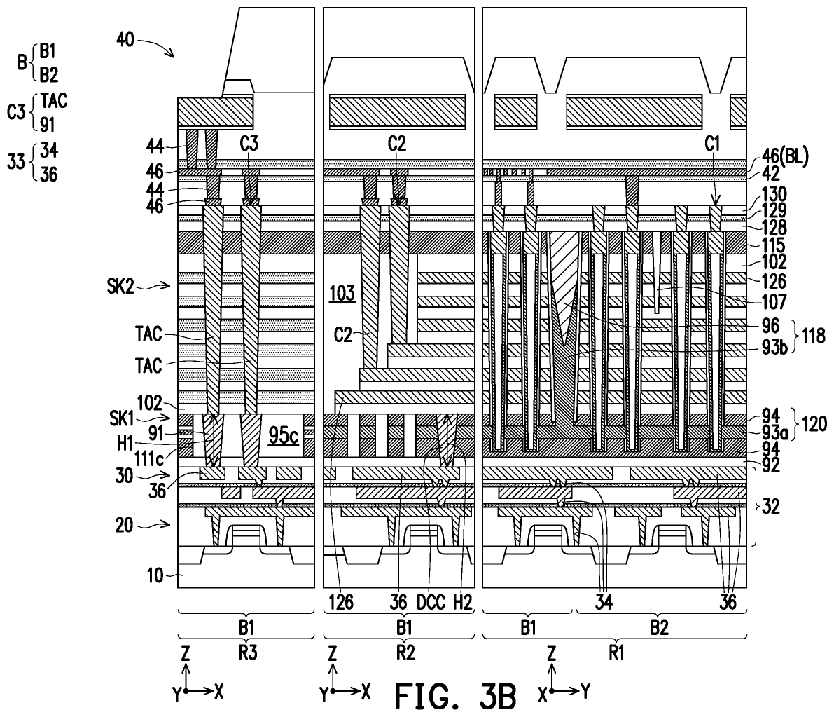

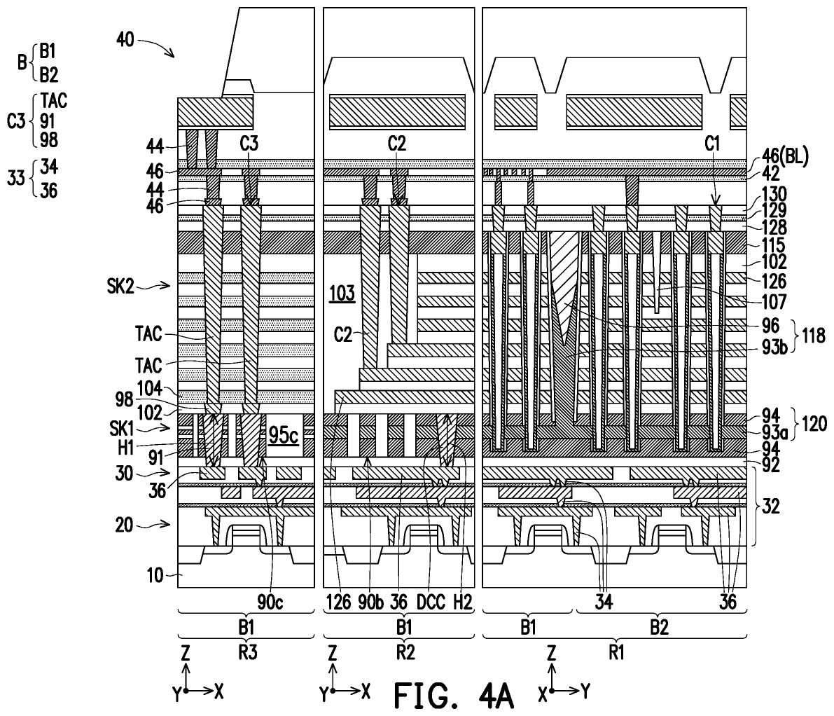

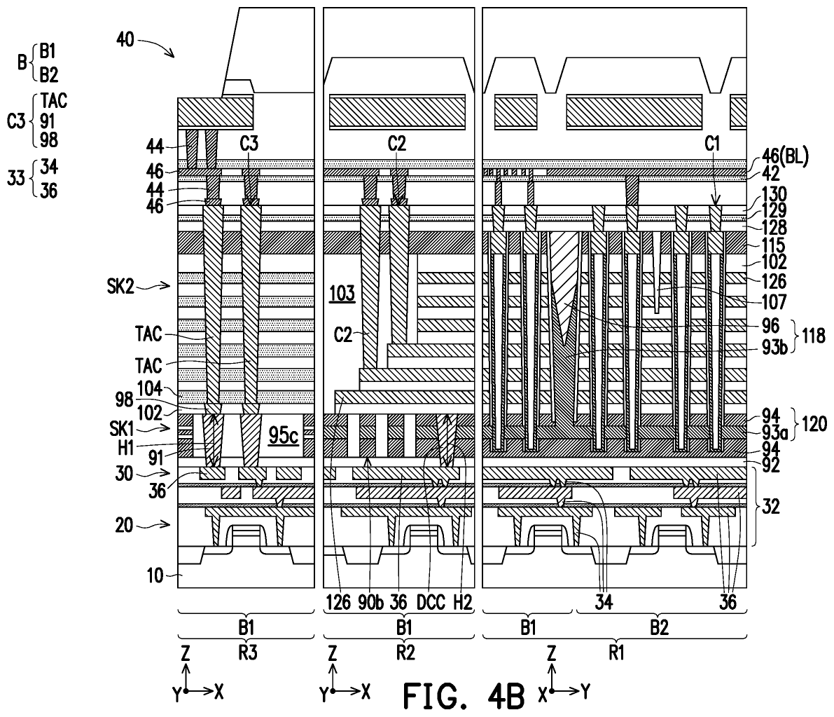

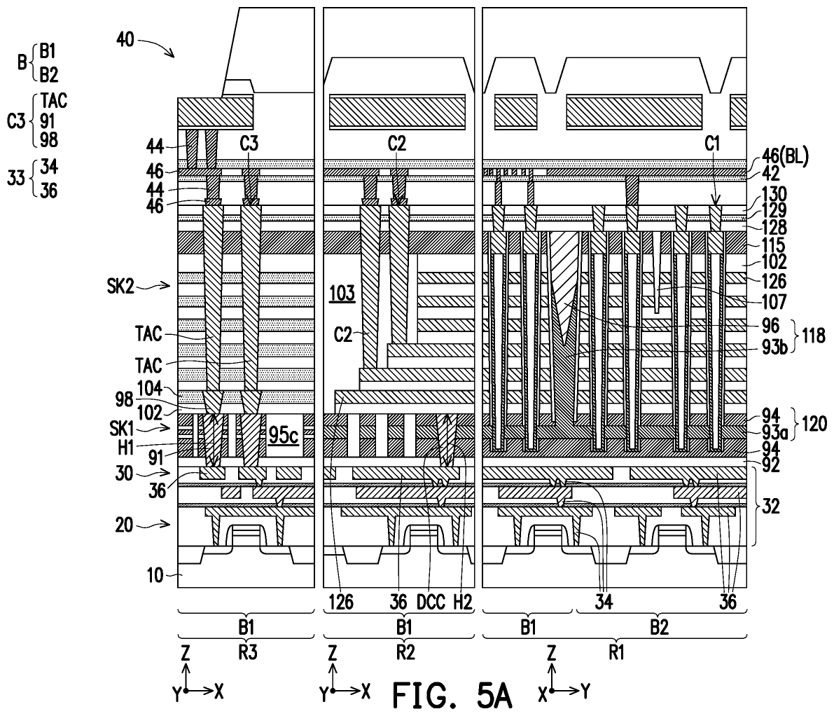

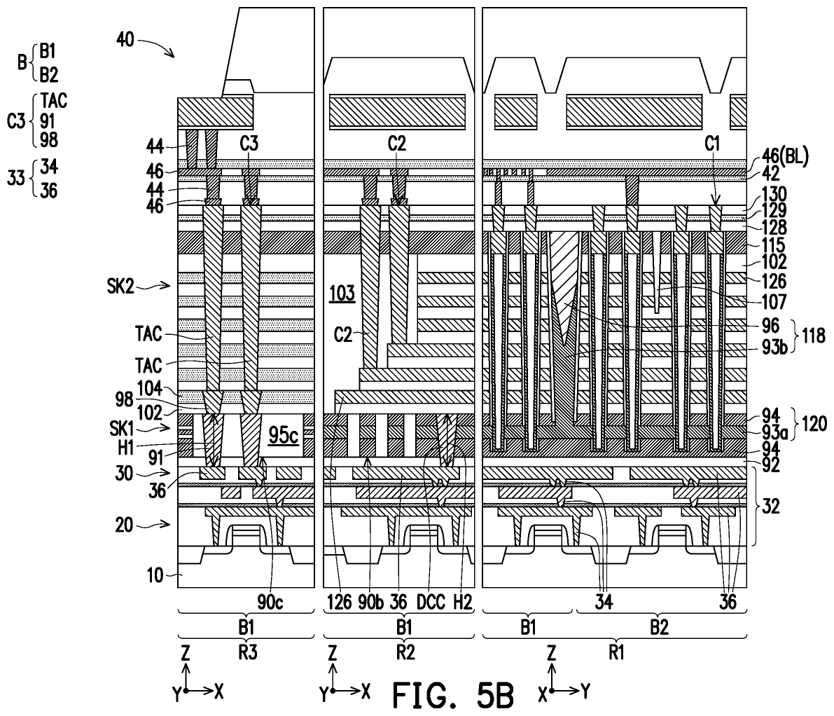

FIG. 1A to FIG. 1M are schematic cross-sectional views showing a method of fabricating a three-dimensional memory device according to an embodiment of the disclosure. FIG. 2, FIG. 3A, FIG. 3B, FIG. 4A, FIG. 4B, FIG. 5A, and FIG. 5B are schematic cross-sectional views showing three-dimensional memory devices according to multiple embodiments of the disclosure. In FIG. 1A to FIG. 1M, FIG. 2, FIG. 3A, FIG. 3B, FIG. 4A, FIG. 4B, FIG. 5A and FIG. 5B, a first region R1 is a schematic cross-sectional view along the Y direction, and a second region R2 and a third region R3 are schematic cross-sectional views along the X direction.

Referring to FIG. 1A, a substrate 10 is provided. The substrate 10 includes a first region R1, a second region R2, and a third region R3. The first region R1, the second region R2, and the third region R3 may also be referred to as a memory array region R1, a staircase region R2, and a periphery region R3. The substrate 10 may be a semiconductor substrate, such as a silicon-containing substrate.

A device layer 20 is formed on the substrate 10. The device layer 20 may include an active device or a passive device. The active device is, for example, a transistor, a diode, etc. The passive device is, for example, a capacitor, an inductor, etc. The transistor may be an N-type metal-oxide-semiconductor (NMOS) transistor, a P-type metal-oxide-semiconductor (PMOS) transistor, or a complementary metal-oxide-semiconductor (CMOS).

A metal interconnect structure 30 is formed on the device layer 20. The metal interconnect structure 30 may include a plurality of dielectric layers 32 and a metal interconnect 33 formed in the dielectric layers 32. The metal interconnect 33 includes a plurality of plugs 34, a plurality of conductive lines 36, etc. The dielectric layer 32 separates adjacent conductive lines 36. The conductive lines 36 may be connected to each other through the plug 34, and the conductive lines 36 may be connected to the device layer 20 through the plugs 34.

A stack structure SK1 is formed on the metal interconnect structure 30. The stack structure SK1 includes a plurality of insulating layers 92 and a plurality of conductive layers 94 stacked alternately on each other along the Z direction. In an embodiment, the material of the insulating layer 92 includes silicon oxide, and the material of the conductive layer 94 includes doped polysilicon. The numbers of the insulating layers 92 and the conductive layers 94 are not limited to those shown in the figures. Since a memory array will be formed right above the stack structure SK1 in the first region R1, and the device layer 20 is, for example, a complementary metal-oxide-semiconductor (CMOS) formed below the memory array, this architecture may also be referred to as a CMOS-Under-Array (CUA) structure.

Referring to FIG. 1B, the stack structure SK1 is patterned to form grooves 111b in the second region R2 and form grooves 111c in the third region R3. The stack structure SK1 in the second region R2 and the third region R3 is patterned into a plurality of dummy structures 90b and 90c separate from each other. The dummy structures 90b and 90c may have an island shape. In a top view, the island shape may be a circle, an oval, a square with rounded corners, or a rectangle with rounded corners.

An insulating material (e.g., silicon oxide) is filled in the grooves 111b and 111c, and then, a chemical-mechanical planarization process is performed to remove the excessive insulating material and form insulating structures 95b and 95c in the grooves 111b and 111c. The insulating structures 95b and 95c respectively surround the dummy structures 90b and 90c.

Referring to FIG. 1B, lithography and etching processes are performed to form an opening OP1 in the stack structure SK1 at the boundary between the second region R2 and the first region R1. The opening OP1 is, for example, a hole or a trench. The opening OP1 exposes the surface of the conductive line 36. The etching process is, for example, a dry etching process, a wet etching process, or a combination thereof. The shape of the opening OP1 may be a cylinder, an elliptic cylinder, a cuboid, etc. and is not particularly limited.

Next, a conductive pillar DCC is formed in the opening OP1. The conductive pillar DCC has a low resistance. In an embodiment, the conductive layer 94 is doped polysilicon, and the conductive pillar DCC is tungsten, titanium nitride, tantalum, or a combination thereof. The resistance of the conductive pillar DCC is lower than the resistance of the conductive layer 94. The method of forming the conductive pillar DCC includes, for example, forming a conductive material on the stack structure SK1 and in the opening OP1, and then, performing a planarization process such as an etch-back process or a chemical-mechanical polishing process to remove the excessive conductive material on the stack structure SK1. The conductive pillar DCC is electrically connected to the topmost conductive line 36. In some embodiments, the topmost conductive line 36 electrically connected to the conductive pillar DCC is electrically connected to the substrate 10 and grounded. Therefore, the conductive pillar DCC may serve as a discharge path. In this embodiment, the conductive pillar DCC extends from the top surface of the stack structure SK1 to the bottom surface of the stack structure SK1. However, the embodiment of the disclosure is not limited thereto, and the conductive pillar DCC may extend from any one of the insulating layers 92 or the conductive layers 94 of the stack structure SK1, pass through the bottommost insulating layer 92, and extend to the bottom surface of the stack structure SK1 to be electrically connected to the conductive line 36.

Referring to FIG. 1C, a bottommost insulating layer 102 of a stack structure SK2 is formed on the substrate 10. Then, lithography and etching processes are performed to form an opening OP2 in the dummy structure 90c in the third region R3, and then a conductive pillar 91 is formed in the opening OP2. The material of the conductive pillar 91 is, for example, tungsten, titanium nitride, tantalum, or a combination thereof. The method of forming the conductive pillar 91 includes, for example, forming a conductive material on the insulating layer 102 and in the opening OP2, and then, performing a planarization process such as an etch-back process or a chemical-mechanical polishing process to remove the excessive conductive material on the insulating layer 102. The conductive pillar 91 passes through the insulating layer 102 and the stack structure SK1 and is electrically connected to the topmost conductive line 36. In this embodiment, a height H1 of the conductive pillar 91 is greater than a height H2 of the conductive pillar DCC. However, the embodiment of the disclosure is not limited thereto, and the conductive pillar 91 may also extend from any one of the insulating layers 92 or the conductive layers 94 of the stack structure SK1, pass through the bottommost insulating layer 92, and extend to the bottom surface of the stack structure SK1 to be electrically connected to the conductive line 36. Therefore, the height H1 of the conductive pillar 91 may also be equal to or less than the height H2 of the conductive pillar DCC, which will be described in detail later.

Referring to FIG. 1D, next, a stack structure SK2 is formed on the substrate 10. The stack structure SK2 includes a plurality of insulating layers 102 and a plurality of middle layers 104 stacked alternately on each other.

In an embodiment, the material of the insulating layer 102 includes silicon oxide, and the material of the middle layer 104 includes silicon nitride. Then, a stop layer 105 is formed on the stack structure SK2. The middle layers 104 may serve as sacrificial layers and may be partially removed or completely removed. The material of the stop layer 105 is different from the materials of the insulating layer 102 and the middle layer 104, and is, for example, polysilicon.

Referring to FIG. 1E, the middle layers 104 and the insulating layers 102 of the stack structure SK2 in the second region R2 are patterned to form a staircase structure SC. In some embodiments, the staircase structure SC may be formed through a multi-stage patterning process, but the disclosure is not limited thereto. The patterning process may include processes such as lithography, etching, and trimming.

Referring to FIG. 1E and FIG. 1F, a dielectric layer 103 is formed on the substrate 10 to cover the staircase structure SC. The material of the dielectric layer 103 is, for example, silicon oxide. The method of forming the dielectric layer 103 includes, for example, forming a dielectric material layer to fill and cover the staircase structure SC. Afterwards, with the stop layer 105 serving as a polishing stop layer, a planarization process such as a chemical-mechanical polishing process is performed to remove the dielectric material layer higher than the stop layer 105. Next, the stop layer 105 is removed. An insulating cap layer 115 is formed on the stack structure SK2. In an embodiment, the material of the insulating cap layer 115 includes silicon oxide.

Referring to FIG. 1G, a patterning process is performed to remove part of the insulating cap layer 115, part of the stack structure SK2, and part of the stack structure SK1 in the first region R1 to form one or more openings 106 passing through the insulating cap layer 115, the stack structure SK2, and the stack structure SK1. In an embodiment, the opening 106 may have a slightly inclined sidewall, as shown in FIG. 1G. In another embodiment, the opening 106 may have a substantially vertical sidewall (not shown). In an embodiment, the opening 106 is also referred to as a vertical channel (VC) opening. In an embodiment, the opening 106 may be formed through one-stage lithography and etching processes. In another embodiment, the opening 106 may be formed through multi-stage lithography and etching processes. In the etching process of forming the opening 106, the conductive pillar DCC may serve as a discharge path, so that the later formed upper portion of the opening 106 can be aligned with the earlier formed lower portion of the opening 106 that is located below. The contour of the sidewall of the opening 106 formed through multi-stage lithography and etching processes may be in a segmental shape, for example. Next, a vertical channel pillar CP is formed in the opening 106. The vertical channel pillar CP may be formed by a method described below.

First, referring to FIG. 1G again, a charge storage structure 108 is formed on the sidewall of the opening 106. The charge storage structure 108 is in contact with the insulating cap layer 115, the insulating layers 102, the middle layers 104, the insulating layers 92, and the conductive layers 94. In an embodiment, the charge storage structure 108 is an oxide/nitride/oxide (ONO) composite layer. The charge storage structure 108 is formed on the sidewall of the opening 106 in the form of a spacer and exposes the bottom surface of the opening 106.

Next, referring to FIG. 1G again, a channel layer 110 is formed on the charge storage structure 108. In an embodiment, the material of the channel layer 110 includes polysilicon. In an embodiment, the channel layer 110 covers the charge storage structure 108 on the sidewall of the opening 106 and also covers the bottom surface of the opening 106. Next, an insulating pillar 112 is formed at the lower portion of the opening 106. In an embodiment, the material of the insulating pillar 112 includes silicon oxide. Afterwards, a conductive plug 114 is formed at the upper portion of the opening 106, and the conductive plug 114 is in contact with the channel layer 110. In an embodiment, the material of the conductive plug 114 includes polysilicon. The channel layer 110, the insulating pillar 112, and the conductive plug 114 may be collectively referred to as a vertical channel pillar CP. The charge storage structure 108 surrounds the vertical outer surface of the vertical channel pillar CP.

In some embodiments, when the opening 106, the charge storage structure 108, and the vertical channel pillar CP are formed, a support structure (not shown) may also be formed in the second region R2 at the same time to prevent collapse of the staircase structure SC in a subsequent removal process of the middle layers 104. The support structure (not shown) may have the same structure as the structure of the combination of the charge storage structure 108 and the vertical channel pillar CP, but the disclosure is not limited thereto. In other embodiments, the support structure may be separately formed, and its structure may be different from the structure of the combination of the charge storage structure 108 and the vertical channel pillar CP.

Referring to FIG. 1G again, a patterning process is performed on the stack structure SK2 to form a plurality of trenches 116. The trench 116 extends in the X direction and passes through the insulating cap layer 115 and the stack structure SK2 to divide the stack structure SK2 into a plurality of blocks B (e.g., a block B1 and a block B2). In an embodiment, the trench 116 may have a slightly inclined sidewall, as shown in FIG. 1G. In another embodiment, the trench 116 may have a substantially vertical sidewall (not shown). The trench 116 exposes the sidewalls of the insulating cap layer 115, the middle layers 104, and the insulating layers 102.

Referring to FIG. 1H, afterwards, a replacement process is performed to replace the middle layers 104 in the first region R1 and the second region R2 with conductive layers 126. First, a selective etching process is performed, so that an etchant passes by the trench 116 and the stack structure SK2 on its two sides. Accordingly, the middle layers 104 in the first region R1 and the second region R2 are removed to form a plurality of horizontal openings 121. The horizontal opening 121 exposes part of the charge storage structure 108 in the first region R1, the upper and lower surfaces of the insulating layer 102, and the sidewall of the dielectric layer 103, and exposes part of the sidewall of the support structure (not shown). The selective etching process may be isotropic etching such as a wet etching process. The etchant used in the wet etching process is, for example, a hot phosphoric acid. The middle layers 104 in the third region R3 are shielded by the dielectric layer 103 so they will not be removed and will be retained.

Then, a conductive layer 126 is formed in the trench 116 and the horizontal opening 121 and the conductive layer 126 may be serve as a gate layer 126. The conductive layer 126 includes, for example, a barrier layer 122 and a metal layer 124. In an embodiment, the material of the barrier layer 122 includes titanium (Ti), titanium nitride (TiN), tantalum (Ta), tantalum nitride (TaN), or a combination thereof, and the material of the metal layer 124 includes tungsten (W).

Referring to FIG. 1I and FIG. 1J, next, a spacer 117 is formed on the sidewall of the trench 116. The spacer 117 includes a dielectric material different from the material of the insulating layer 102, and may be, for example, silicon nitride or a silicon oxide/silicon nitride/silicon oxide composite layer. Afterwards, the depth of the trench 116 is increased, the middle conductive layer 94 of the stack structure SK1 in the first region R1 and the second region R2 is removed, and then the insulating layers 92 on and below the middle conductive layer 94 are removed, to form a horizontal opening 123 in the stack structure SK1. Then, a conductive layer 93, such as a doped polysilicon layer, is filled in the trench 116 and the horizontal opening 123. A conductive layer 93a in the horizontal opening 123 and the conductive layers 94 on and below the conductive layer 93a collectively form a source line 120. After the source line 120 is formed, the conductive pillar DCC is embedded in the source line 120. The conductive layer 93 in the trench 116 is etched back to form a conductive layer 93b, and a groove is formed on the conductive layer 93b. Next, a conductive pad 96 is formed in the groove on the conductive layer 93b. The material of the conductive pad 96 is, for example, tungsten. The conductive pad 96 and the conductive layer 93b collectively form a source line slit 118 for conducting a current from the source line 120. The source line slit 118 is insulated by the spacer 117 to avoid contact with the conductive layers 126.

Referring to FIG. 1J, a selective source line cut slit 107 extending in the X direction is formed in part of the insulating cap layer 115 and part of the stack structure SK2 of each block B. The selective source line cut slit 107 is an insulating material such as silicon oxide and separates the upper conductive layers 126 of the stack structure SK2 of each block B from each other. The timing of forming the selective source line cut slit 107 is not limited thereto, and the selective source line cut slit 107 may also be formed in advance, for example, before the staircase structure SC is formed.

Referring to FIG. 1K, next, a dielectric layer 128, a stop layer 129, and a dielectric layer 130 are formed on the insulating cap layer 115. The dielectric layers 128 and 130 are, for example, silicon oxide, and the stop layer 129 is, for example, silicon nitride. Afterwards, lithography and etching processes are performed to form contact openings OP3, OP4, and OP5 respectively in the first region R1, the second region R2, and the third region R3. The contact opening OP3 passes from the dielectric layer 130 through the dielectric layer 128 and exposes the conductive plug 114 of the vertical channel pillar CP. The contact opening OP4 extends from the dielectric layer 130, passes through the dielectric layer 103, and exposes the top surface of the conductive layer 126 of the staircase structure SC. The contact opening OP5 extends from the dielectric layer 130, passes through the stack structure SK2, and exposes the top surface of the conductive pillar 91. In the disclosure, the formation of the contact opening OP5 and the formation of the contact opening OP4 may be merged in the same lithography and etching processes. During etching, after the contact opening OP4 is formed, the same etching conditions may be applied or the etching conditions may be fine-tuned to continue etching to form the contact opening OP5. Since the difference between the depths of the contact openings OP5 and OP4 is small, the conductive layer 126 below the contact opening OP4 will not be etched through during the continued etching process. In addition, since the contact opening OP5 may land on the top surface of the conductive pillar 91 without passing through the metal interconnect structure 30, the aspect ratio of the contact opening OP5 can be reduced to avoid arcing defects caused by an excessively high aspect ratio.

Referring to FIG. 1L, next, contacts C1, C2, and TAC are formed respectively in the contact openings OP3, OP4, and OP5. The contact C1 lands on the conductive plug 114 of the vertical channel pillar CP and is electrically connected to the conductive plug 114. The contact C2 passes through the dielectric layer 103, lands on the surface of the end of the conductive layer 126 of the staircase structure SC, and is electrically connected to the conductive layer 126. The contact TAC may also be referred to as a through array contact. The contact TAC passes form the dielectric layer 130, through the insulating cap layer 115 and the stack structure SK2, lands on the surface of the conductive pillar 91, and is electrically connected to the conductive pillar 91. In an embodiment, each of the contacts C2 and TAC may include a barrier layer and a conductive layer. The material of the barrier layer is, for example, titanium (Ti), titanium nitride (TiN), tantalum (Ta), tantalum nitride (TaN), or a combination thereof, and the material of the conductive layer is, for example, tungsten (W). The method of forming the contacts C2 and TAC includes, for example, first sequentially forming a barrier layer and a conductive layer on the dielectric layer 130 and in the contact openings OP4 and OP5, and then performing a planarization process by a chemical-mechanical polishing method.

Referring to FIG. 1M, a metal interconnect structure 40 is formed. The metal interconnect structure 40 may include a plurality of dielectric layers 42 and a plurality of plugs 44, a plurality of conductive lines 46, etc. formed in the dielectric layers 42. The dielectric layer 42 separates adjacent conductive lines 46. The conductive lines 46 may be connected to each other through the plug 44, and the conductive lines 46 may be respectively electrically connected to the contacts C1, C2, and TAC. The conductive line 46 connected to the contact C1 may serve as a bit line BL.

Afterwards, subsequent fabrication processes are performed to complete the fabrication of the memory device.

In this embodiment, a contact C3 in the third region (periphery region) R3 includes the conductive pillar 91 and the contact TAC and may be formed in two stages. The contact TAC lands on the conductive pillar 91, and the conductive pillar 91 is embedded in the bottommost insulating layer 102 of the stack structure SK2 and the dummy structure 90c of the stack structure SK1, as shown in FIG. 1M.

Referring to FIG. 2, the conductive pillar 91 of the disclosure may also be directly embedded in the bottommost insulating layer 102 of the stack structure SK2 and the insulating structure 95c, instead of being embedded in the dummy structure 90c as shown in FIG. 1M. In other words, when the stack structure SK1 is patterned, a larger groove 111c is formed in the third region R3, and the insulating structure 95c is filled in the groove 111c without any dummy structure, so the conductive pillar 91 may also be directly embedded in the insulating structure 95c.

In the above embodiment, the conductive pillar 91 is formed after the conductive pillar DCC is formed, and a height H1 of the conductive pillar 91 is greater than a height H2 of the conductive pillar DCC. However, the disclosure is not limited thereto. Referring to FIG. 3A and FIG. 3B, the conductive pillar 91 may be formed at the same time when the conductive pillar DCC is formed, and the height H1 of the conductive pillar 91 is substantially equal to the height H2 of the conductive pillar DCC. In FIG. 3A, the conductive pillar 91 is embedded in the dummy structure 90c surrounded by the insulating structure 95c, and the conductive pillar DCC is embedded in the source line 120. In FIG. 3B, the conductive pillar 91 is embedded in the insulating structure 95c, and the conductive pillar DCC is embedded in the source line 120. In FIG. 3A and FIG. 3B, the contact TAC passes through the bottommost insulating layer 102 of the stack structure SK2 and directly lands on the conductive pillar 91.

In the above embodiment, the contact C3 in the third region (periphery region) R3 is formed in two stages, and the contact TAC directly lands on the conductive pillar 91. However, referring to FIG. 4A, FIG. 4B, FIG. 5A, and FIG. 5B, the contact C3 in the third region (periphery region) R3 is formed in three stages, and the contact TAC and the conductive pillar 91 are connected to each other through a connection pad 98.

Referring to FIG. 4A and FIG. 4B, the connection pad 98 is formed in the bottommost insulating layer 102 of the stack structure SK2. For example, the method of forming the connection pad 98 may be as follows. After the bottommost insulating layer 102 of the stack structure SK2 is formed, patterning is performed through lithography and etching processes to form an opening (not shown) that exposes the top surface of the conductive pillar 91. Next, a conductive layer is filled in the opening. Then, planarization is performed by a chemical-mechanical polishing process to remove the excessive conductive layer on the surface of the bottommost insulating layer 102. Accordingly, the subsequently formed contact TAC may land on the connection pad 98.

Referring to FIG. 5A and FIG. 5B, the connection pad 98 is not only formed in the bottommost insulating layer 102 of the stack structure SK2, but also extends upward into the bottommost middle layer 104. The method of forming the connection pad 98 may be as follows, for example. After the bottommost insulating layer 102 and the bottommost middle layer 104 of the stack structure SK2 are formed, patterning is performed through lithography and etching processes to form an opening (not shown) that exposes the top surface of the conductive pillar 91. Next, a conductive layer is filled in the opening. Then, planarization is performed by a chemical-mechanical polishing process to remove the excessive conductive layer on the surface of the bottommost middle layer 104. Accordingly, the subsequently formed contact TAC may land on the connection pad 98.

The formation of the connection pad 98 can further reduce the depth of the contact TAC. The contact TAC formed in this method has a height very close to the height of the contact C2 connected to the bottommost conductive layer 126. In other words, after the contact opening OP4 is formed, the time for continuing etching to form the contact opening OP5 can be shortened. Therefore, it is possible to reduce the possibility of etching through the conductive layer 126 below the contact opening OP4, and the aspect ratio of the contact opening OP5 can be further reduced to thereby reduce the risk of arcing defects.

In the embodiment of the disclosure, the contact in the third region (periphery region) may be formed in two stages, three stages, or more stages, and is not limited to those described in the above embodiment. Therefore, the contact may be divided into two parts, three parts, or more parts. In FIG. 1M, FIG. 2, FIG. 3A, and FIG. 3B, the contact in the third region (periphery region) includes two parts (i.e., the conductive pillar 91 and the contact TAC). In FIG. 4A, FIG. 4B, FIG. 5A and FIG. 5B, the contact in the third region (periphery region) includes three parts (i.e., the conductive pillar 91, the connection pad 98, and the contact TAC).

In the embodiment of the disclosure, the conductive pillar is disposed below through array contact, which can reduce the etching depth of the contact opening and reduce the risk of arcing defects. Moreover, the difference between the depths of the contact openings in different regions can be reduced, so that the through array contact opening in the third region can be prevented from being too deep and causing over-etching of the contact openings in other regions (e.g., the second region) and thus causing etch-through of the gate layer. Therefore, the disclosure may merge the fabrication processes of contact openings of different regions into the same step, which saves the manufacturing cost and increases the process window.

What is claimed is:

1. A memory device comprising:
a substrate;
a metal interconnect structure located on the substrate;
a first stack structure located on the metal interconnect structure and comprising:
a plurality of first conductive layers and a plurality of first insulating layers that alternate with each other; and
an insulating structure embedded in the first conductive layers and the first insulating layers;
a second stack structure located on the first stack structure and comprising a plurality of second insulating layers and a plurality of middle layers that alternate with each other;
a first conductive pillar embedded in the insulating structure to be electrically connected to the metal interconnect structure; and
a first contact passing through the second insulating layers and the middle layers of the second stack structure to be electrically connected to the first conductive pillar.

2. The memory device according to claim 1, wherein the first contact lands on the first conductive pillar.

3. The memory device according to claim 1, further comprising a connection pad located between the first contact and the first conductive pillar.

4. The memory device according to claim 1, wherein the first stack structure further comprises a dummy structure embedded in the insulating structure, and the first conductive pillar is surrounded by the dummy structure.

5. The memory device according to claim 4, wherein the dummy structure comprises the plurality of first conductive layers and the plurality of first insulating layers that alternate with each other.

6. The memory device according to claim 4, wherein the dummy structure has an island shape.

7. The memory device according to claim 1, further comprising a second conductive pillar that is embedded in a common source conductive layer of the first stack structure and is electrically connected to the common source conductive layer and the metal interconnect structure.

8. The memory device according to claim 7, wherein a height of the first conductive pillar is equal to a height of the second conductive pillar.

9. The memory device according to claim 7, wherein a height of the first conductive pillar is greater than a height of the second conductive pillar.

10. The memory device according to claim 1, wherein
the second stack structure comprises the plurality of second insulating layers and a plurality of second conductive layers that alternate with each other, and
the memory device further comprises:
a channel pillar passing through the second insulating layers and the second conductive layers of the second stack structure and extending to the first stack structure; and
a storage layer located between the channel pillar and the first stack structure and between the channel pillar and the second stack structure.

11. The memory device according to claim 10, wherein
the second stack structure comprises:
a staircase structure comprising the plurality of second insulating layers and the plurality of second conductive layers that alternate with each other; and
a dielectric layer covering the staircase structure, and
the memory device further comprises:
a plurality of second contacts passing through the dielectric layer and electrically connected to the second conductive layers of the staircase structure.

12. A method of fabricating a memory device, comprising:
forming a metal interconnect structure on a substrate;
forming a first stack structure on the metal interconnect structure, wherein the first stack structure comprises a plurality of first conductive layers and a plurality of first insulating layers that alternate with each other;
forming an insulating structure in the first stack structure;
forming a first conductive pillar in the insulating structure;
forming a second stack structure on the first stack structure, the insulating structure, and the first conductive pillar, wherein the second stack structure comprises a plurality of second insulating layers and a plurality of middle layers that alternate with each other; and
forming a first contact passing through the second insulating layers and the middle layers of the second stack structure to be electrically connected to the first conductive pillar.

13. The method of fabricating a memory device according to claim 12, wherein the first contact is formed to land on the first conductive pillar.

14. The method of fabricating a memory device according to claim 12, further comprising forming a connection pad on the first conductive pillar, and forming the first contact to land on the connection pad.

15. The method of fabricating a memory device according to claim 12, further comprising partially patterning the first stack structure into a dummy structure, forming the insulating structure around the dummy structure, and forming the first conductive pillar to pass through the dummy structure.

16. The method of fabricating a memory device according to claim 15, wherein the dummy structure is formed in an island shape.

17. The method of fabricating a memory device according to claim 12, further comprising:
before forming the second stack structure, forming a second conductive pillar in the first stack structure to be electrically connected to the metal interconnect structure.

18. The method of fabricating a memory device according to claim 17, wherein the first conductive pillar and the second conductive pillar are formed at the same time, and a height of the first conductive pillar is equal to a height of the second conductive pillar.

19. The method of fabricating a memory device according to claim 17, wherein the first conductive pillar is formed after the second conductive pillar is formed, and a height of the first conductive pillar is greater than a height of the second conductive pillar.

20. The method of fabricating a memory device according to claim 17, further comprising:
patterning the second stack structure to form a staircase structure;
forming a dielectric layer covering the staircase structure;
forming a channel pillar that passes through the plurality of second insulating layers and a plurality of middle layers of the second stack structure and extends to the first stack structure;
forming a storage layer between the channel pillar and the first stack structure and between the channel pillar and the second stack structure;
partially replacing the plurality of middle layers of the second stack structure with a plurality of second conductive layers;
partially removing the plurality of first insulating layers of the first stack structure to form a plurality of horizontal openings, and filling a conductive material in the horizontal openings to form a common source conductive layer together with the first conductive layers; and
forming a plurality of second contacts at the same time as forming the first contact, wherein the second contacts pass through the dielectric layer and are electrically connected to the second conductive layers of the staircase structure.
